(19) United States
(12) Patent Application Publication
(10) Pub. No.: US 2017/0317273 A1
(43) Pub. Date: Nov. 2, 2017

(54) Method for Forming Perpendicular Magnetization Type Magnetic Tunnel Junction Element and Apparatus for Producing Perpendicular Magnetization Type Magnetic Tunnel Junction Element

(71) Applicant: TOKYO ELECTRON LIMITED, Tokyo (JP)

(72) Inventors: Toru KITADA, Nirasaki City (JP); Kanto NAKAMURA, Nirasaki City (JP); Atsushi GOMI, Nirasaki City (JP); Shinji FURUKAWA, Nirasaki City (JP); Yusuke SUZUKI, Beaverton, OR (US)

(21) Appl. No.: 15/652,816

(22) Filed: Jul. 18, 2017

Related U.S. Application Data
(63) Continuation of application No. PCT/JP2016/050265, filed on Jan. 6, 2016.

(30) Foreign Application Priority Data
Jan. 20, 2015 (JP) 2015-008528

(51) Int. Cl. H01L 43/12; H01L 43/08; H01F 41/18; H01F 10/32; C23C 14/08; H01F 10/16; C23C 14/58; C23C 14/34; H01L 43/10

(52) U.S. Cl. CPC H01L 43/12; H01L 43/10; H01L 43/08; H01F 41/18; H01F 10/3286; C23C 14/082; H01F 10/16; C23C 14/5853; C23C 14/34; H01F 10/3254

(57) ABSTRACT

A method for forming a perpendicular magnetization type magnetic tunnel junction element includes forming a tunnel barrier layer on a first magnetic layer of a workpiece, cooling the workpiece on which the tunnel barrier layer is formed, and forming a second magnetic layer on the tunnel barrier layer after the cooling.

### CROSS-REFERENCE TO RELATED APPLICATIONS

This application is a Continuation application of PCT International Application No. PCT/JP2016/050265, filed Jan. 6, 2016, which claimed the benefit of Japanese Patent Application No. 2015-008528, filed Jan. 20, 2015, the entire content of each of which is hereby incorporated by reference

### TECHNICAL FIELD

The present disclosure relates to a method for forming a perpendicular magnetization type magnetic tunnel junction element and an apparatus for producing a perpendicular magnetization type magnetic tunnel function element.

### BACKGROUND

In an electronic device using a tunnel magneto-resistance (TMR) effect such as a magnetoresistive random access memory (MRAM) or the like, a magnetic tunnel junction (MTJ) element is used.

Such an MTJ element has two magnetic layers and a tunnel barrier layer formed between these two magnetic layers. In manufacturing the MTJ element configured as above, the tunnel barrier layer is formed on a first magnetic layer and a second magnetic layer is subsequently formed on the tunnel barrier layer. In order to form these layers of the MTJ element, a film forming apparatus such as a sputtering apparatus is generally used. Further, in the related art, the manufacturing of such an MTJ element is known.

Incidentally, one type of MTJ element includes a perpendicular magnetization type MTJ element. In the perpendicular magnetization type MTJ element, when a perpendicular magnetic anisotropic energy is lower than a thermal energy, a magnetic substance fluctuates in a magnetization direction, i.e., thermal disturbance occurs. This makes it difficult to maintain functionality as a memory device.

Thus, the perpendicular magnetic anisotropic energy of the perpendicular magnetization type MTJ element should be enhanced.

### SUMMARY

According to one embodiment of the present disclosure, there is provided a method for forming a perpendicular magnetization type magnetic tunnel junction element, which: forming a tunnel barrier layer on a first magnetic layer of a workpiece; cooling the workpiece on which the tunnel barrier layer is formed; and forming a second magnetic layer on the tunnel barrier layer after the cooling.

In another embodiment, there is provided an apparatus for manufacturing a perpendicular magnetization type magnetic tunnel junction element, which includes: a transfer device configured to transfer a workpiece; a first module configured to form a first magnetic layer; a second module configured to form a tunnel barrier layer; a third module configured to cool the workpiece; a fourth module configured to form a second magnetic layer; and a control part configured to control the transfer device, the first module, the second module, the third module, and the fourth module, wherein the control part is configured to control the transfer device, the first module, the second module, the third module, and the fourth module to: transfer the workpiece to the first module; form the first magnetic layer on the workpiece in the first module; transfer the workpiece from the first module to the second module; form the tunnel barrier layer on the first magnetic layer in the second module; transfer the workpiece from the second module to the third module; cool the workpiece in the third module; transfer the workpiece from the third module to the fourth module; and form the second magnetic layer on the tunnel barrier layer in the fourth module.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a method for forming a perpendicular magnetization type magnetic tunnel junction (MTJ) element according to one embodiment of the present disclosure.

FIG. 2 is a cross-sectional view illustrating a perpendicular magnetization type MTJ element manufactured by the method illustrated in FIG. 1.

FIG. 3 is a diagram illustrating a manufacturing apparatus which can be used in implementing the method illustrated in FIG. 1.

FIG. 4 is a cross-sectional view illustrating a workpiece, manufactured in the course of implementing the method illustrated in FIG. 1.

FIGS. 5A and 5B are diagrams illustrating step ST4 of the method illustrated in FIG. 1.

FIG. 6 is a flowchart illustrating one embodiment of step ST5 of the method illustrated in FIG. 1.

FIGS. 7A and 7B are diagrams illustrating step ST5 of the method illustrated in FIG. 1.

FIGS. 8A and 8B are diagrams illustrating step ST5 of the method illustrated in FIG. 1.

FIG. 9 is a diagram illustrating step ST6 of the method illustrated in FIG. 1.

FIGS. 10A and 10B are diagrams illustrating step ST7 of the method illustrated in FIG. 1.

FIG. 11 is a graph illustrating a standardized MR ratio of MTJ elements manufactured according to Experimental example 1 and Comparative experimental example 1.

FIG. 12 is a graph illustrating a magnetization curve of MTJ elements manufactured according to Experimental example 1 and Comparative experimental example 1.

FIG. 13 is a graph illustrating a perpendicular magnetic anisotropic energy of a magnetic layer ML2 of elements manufactured according to Experimental example 2 and Comparative experimental example 2.

FIG. 14 is a graph illustrating a standardized MR ratio of MTJ elements manufactured according to Experimental example 3, Comparative experimental example 3, and Comparative experimental example 4.

FIG. 15 is a graph illustrating a standardized MR ratio of a plurality of MTJ elements manufactured according to Experimental example 4.

### DETAILED DESCRIPTION

Embodiments of the present disclosure will now be described in detail with reference to the accompanying drawings. Further, like or equivalent parts will be denoted by like reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

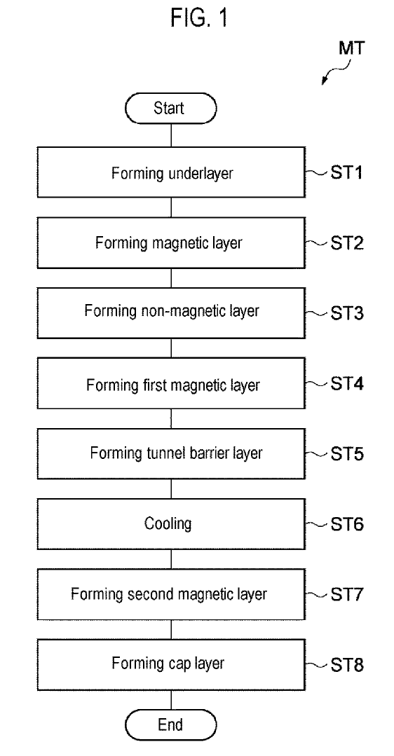

FIG. 1 is a flowchart illustrating a method for forming a perpendicular magnetization type magnetic tunnel junction element according to one embodiment of the present disclosure. A method MT illustrated in FIG. 1 basically includes step ST4 of forming a first magnetic layer, step ST5 of forming a tunnel barrier layer, step ST6 of cooling a workpiece, and step ST7 of forming a second magnetic layer.

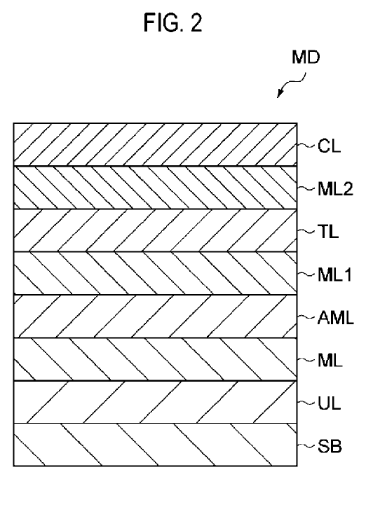

FIG. 2 is a cross-sectional view illustrating a perpendicular magnetization type magnetic tunnel junction element (MTJ element) manufactured by the method illustrated in FIG. 1. The MTJ element (MD) illustrated in FIG. 2 is a so-called top-free type MTJ element. Further, in some embodiments, the MTJ element may be a so-called bottom-free type MTJ element. The top-free type MTJ element illustrated in FIG. 2 includes a substrate SB, an underlayer UL, a magnetic layer ML, a non-magnetic layer AML, a magnetic layer ML1, a tunnel barrier layer TL, a magnetic layer ML2, and a cap layer CL. The magnetic layer ML1 is a first magnetic layer of one embodiment, and the magnetic layer ML2 is a second magnetic layer of one embodiment.

The substrate SB is, for example, a silicon (Si) substrate. The underlayer UL is formed on the substrate SB. In one embodiment, the underlayer UL may be formed of, for example, platinum (Pt) or tantalum (Ta).

The magnetic layer ML1 is formed on the substrate SB with the underlayer UL or the like interposed between the magnetic layer ML1 and the substrate SB. The magnetic layer ML1 is formed of a ferromagnetic material. The magnetic layer ML1 may be formed of cobalt (Co), Co and iron (Fe), or Co, Fe and boron (B). In one embodiment, the magnetic layer ML1 may be formed of CoFeB. Further, the magnetic layer ML2 is formed on the magnetic layer ML1 with the tunnel barrier layer TL interposed between the magnetic layer ML2 and the magnetic layer ML1. That is to say, the tunnel barrier layer TL is formed between the magnetic layer ML1 and the magnetic layer ML2. The tunnel barrier layer TL is formed of an oxide of a metal such as aluminum (Al), titanium (Ti), magnesium (Mg), or zinc (Zn). In one embodiment, the tunnel barrier layer TL may be formed of a magnesium oxide. Further, the magnetic layer ML2 is a memory layer and is formed of a ferromagnetic material similar to that of the magnetic layer ML1. The cap layer CL is formed on the magnetic layer ML2. The cap layer CL may be formed of, for example, Ta.

In the top-free type MTJ element MD illustrated in FIG. 2, the magnetic layer ML, the non-magnetic layer AML, and the magnetic layer ML1 constitutes a fixed layer. The magnetic layer ML is formed on the underlayer UL and the non-magnetic layer AML is formed on the magnetic layer ML. The magnetic layer ML1 is formed on the non-magnetic layer AML. The magnetic layer ML is a layer for fixing a magnetization direction of the magnetic layer ML1.

In a first example, the magnetic layer ML is an artificial lattice film, and forms ferromagnetic bonding with the magnetic layer ML1 via the non-magnetic layer AML. In this example, the magnetic layer ML may be formed by, for example, alternately repeatedly forming a plurality of Co films and a plurality of Pt films, alternately repeatedly forming a plurality of Co films and a plurality of palladium (Pd) films, or alternately repeatedly forming a plurality of Co films and a plurality of nickel (Ni) films. Further, the non-magnetic layer AML may be formed of, for example, ruthenium (Ru).

In a second example, the magnetic layer ML is formed of an alloy which forms ferromagnetic bonds with the magnetic layer ML1. In this example, the magnetic layer ML may be configured by an alloy containing Fe and Pt or an alloy containing Co and Pt. Further, the non-magnetic layer AML may be formed of, for example, Ru.

In a third example, the fixed layer has a stacked ferri-structure, and the magnetic layer ML forms antiferromagnetic bonds with the magnetic layer ML1 via the non-magnetic layer AML.

Referring back to FIG. 1, in the embodiment which forms the MTJ element MD illustrated in FIG. 2, the method MT may further include step ST1 of forming the underlayer UL, step ST2 of forming the magnetic layer ML, step ST3 of forming the non-magnetic layer AML, and step ST8 of forming the cap layer CL.

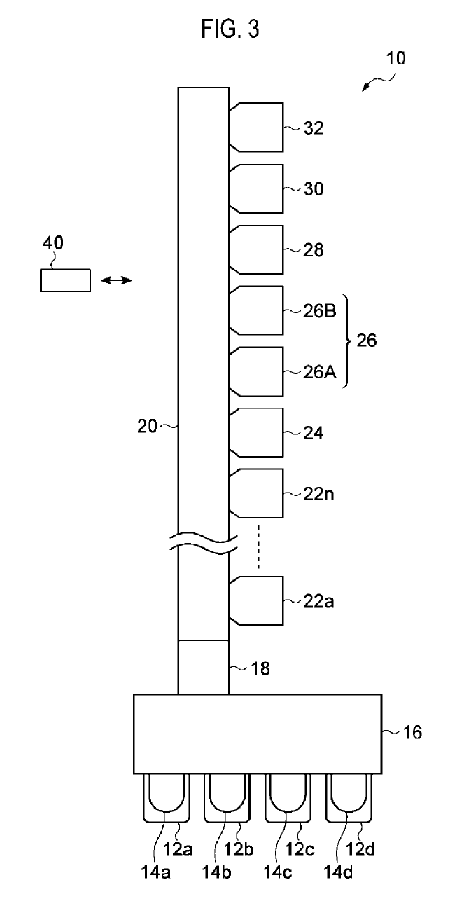

FIG. 3 is a diagram illustrating a manufacturing apparatus which can be used in implementing the method MT illustrated in FIG. 1. A manufacturing apparatus 10 of FIG. 3 includes tables 12a to 12d, receiving containers 14a to 14d, a loader module 16, a load lock chamber 18, a transfer device 20, modules 22a to 22n, a module 24, a module 26, a module 28, a module 30, and a module 32.

The receiving containers 14a to 14d are containers that respectively receive a workpiece (hereinafter, referred to as a “wafer”) therein, and are disposed on the respective tables 12a to 12d. The loader module 16 includes a transfer robot disposed within a chamber that provides an internal space having an atmospheric environment. The transfer robot of the loader module 16 transfers the wafer received in any one of the receiving containers 14a to 14d to the load lock chamber 18.

The load lock chamber 18 provides a preliminary depressurization chamber. When the wafer is loaded into the load lock chamber 18 from the loader module 16, the preliminary depressurization chamber of the load lock chamber 18 is depressurized.

The transfer device 20 includes a chamber that provides a depressurizable internal space and a transfer robot installed inside the chamber. The transfer robot of the transfer device 20 extracts the wafer from the inside of the load lock chamber 18 and sequentially transfers the wafer to the modules 22a to 22n, the module 24, the module 26, the module 28, the module 30, and the module 32 in order to implement the method MT.

The modules 22a to 22n include a module for forming the underlayer UL, one or more modules for forming the magnetic layer ML, and a module for forming the non-magnetic layer AML. The modules 22a to 22n may be a film forming apparatus such as a sputtering apparatus.

The module 24 is a first module configured to form the magnetic layer ML1. Specifically, the module 24 may be a film forming apparatus such as a sputtering apparatus.

The module 26 is a second module configured to form the tunnel barrier layer TL. In one embodiment, the module 26 may include a film forming apparatus 26A and an oxidizing apparatus 26B. The film forming apparatus 26A is an apparatus for forming a film of the aforementioned metal, i.e., Al, Ti, Mg, Zn or the like, on the wafer, and may be, for example, a sputtering apparatus. In one example, the film forming apparatus 26A is configured as a sputtering apparatus for forming a magnesium layer using a target formed of magnesium. The oxidizing apparatus 26B is an apparatus configured to oxidize a metal of the film formed by the film forming apparatus 26A. Specifically, the oxidizing apparatus 26B is configured to heat the wafer under an oxygen atmosphere. In a more specific example, the oxidizing apparatus 26B is configured to supply heated oxygens to the wafer.

Further, the module 26 may be a single film forming apparatus configured to sputter a metal oxide that constitutes the tunnel barrier layer TL. Alternatively, the module 26 may be a single film forming apparatus having a function of forming a metal that constitutes the tunnel barrier layer TL and a function of oxidizing a metal film thus formed.

The module 28 is a third module configured to cool the wafer. In one example, the module 28 may include a process container capable of being depressurized and a stage installed inside the process container. The module 28 may cool the wafer loaded on the stage to a temperature equal to or lower than 200 Kelvin, more specifically, 150 Kelvin. To do this, for example, the module 28 may further include a refrigerator equipped with a cooling head which is coupled to the stage. As such a refrigerator, it may be possible to use a refrigerator based on a Gifford-McMahon cycle (G.M. cycle).

The module 30 is a fourth module configured to form the magnetic layer ML2. The module 30 may be a film forming apparatus such as a sputtering apparatus. Further, the module 32 is configured to form the cap layer CL and may be, for example, a sputtering apparatus.

The manufacturing apparatus 10 further includes a control part 40. The control part 40 may be a computer including a processor, a storage part, an input device, a display device, and the like. The control part 40 controls respective parts of the manufacturing apparatus 10. Specifically, in order to implement the method MT, the control part 40 may store a program for controlling the respective parts of the manufacturing apparatus 10 in the storage part. The control part 40 may perform the method MT by causing the processor to execute the program.

Hereinafter, the method MT will be described in detail with reference back to FIG. 1. Further, in the following description, an example of manufacturing the MTJ element MD illustrated in FIG. 2 by performing the method MT using the manufacturing apparatus 10 will be described.

In the method MT, first, the wafer having the substrate SB is extracted by the transfer robot of the loader module 16 from any one of the receiving containers 14a to 14d. Then, the wafer is transferred to the load lock chamber 18 by the transfer robot of the loader module 16. Subsequently, the wafer received in the load lock chamber 18 is transferred to the module for forming the underlayer UL, among the modules 22a to 22n, by the transfer robot of the transfer device 20. Further, operations of the respective parts of the manufacturing apparatus 10 related to the transfer of the wafer are controlled by the control part 40.

Subsequently, in the method MT, step ST1 is executed. At step ST1, the underlayer UL is formed on the substrate SB of the wafer. To do this, at step ST1, the module for forming the underlayer UL, among the modules 22a to 22n, is controlled by the control part 40. For example, the respective module is controlled to deposit a material that constitutes the underlayer UL on the substrate SB.

Subsequently, in the method MT, the wafer is transferred from the module for forming the underlayer UL to the module for forming the magnetic layer ML by the transfer device 20. Such an operation of the transfer device 20 related to the transfer of the wafer is controlled by the control part 40.

Subsequently, at step ST2, the magnetic layer ML is formed on the underlayer UL. To do this, at step ST2, one or more modules for forming the magnetic layer ML, among the modules 22a to 22n, are controlled by the control part 40. For example, the one or more modules are controlled to deposit the material that constitutes the magnetic layer ML on the underlayer UL. Further, when the magnetic layer ML is constituted by a plurality of films, like the artificial lattice film described above, a plurality of modules are used to form the magnetic layer ML. In this case, at step ST2, the control part 40 controls the transfer device 20 and the plurality of modules such that the wafer is sequentially transferred to the plurality of modules and films are sequentially formed in the plurality of modules.

Subsequently, in the method MT, the wafer is transferred from the module for forming the magnetic layer ML to the module for forming the non-magnetic layer AML by the transfer device 20. Such an operation of the transfer device 20 related to the transfer of the wafer is controlled by the control part 40.

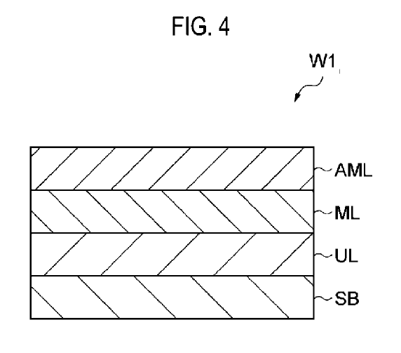

Subsequently, at step ST3, the non-magnetic layer AML is formed on the magnetic layer ML. To do this, at step ST3, the module for forming the non-magnetic layer AML, among the modules 22a to 22n, is controlled by the control part 40. For example, the respective module is controlled to deposit a material that constitutes the non-magnetic layer AML on the magnetic layer ML. Thus, as illustrated in FIG. 4, a wafer W1 in which the underlayer UL, the magnetic layer ML, and the non-magnetic layer AML are sequentially formed on the substrate SB is obtained.

Subsequently, in the method MT, the wafer W1 is transferred from the module for forming the non-magnetic layer AML to the module 24 by the transfer device 20. Such an operation of the transfer device 20 related to the transfer of the wafer W1 is controlled by the control part 40.

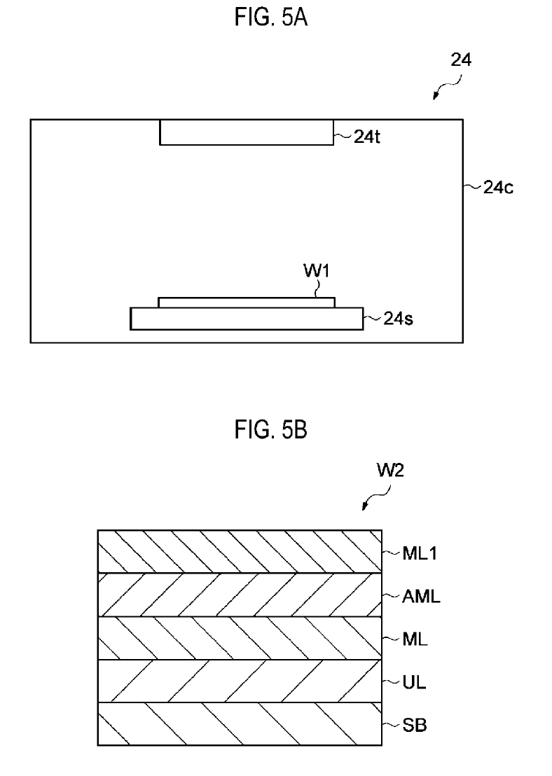

Subsequently, at step ST4, the magnetic layer ML1 is formed on the non-magnetic layer AML. To do this, at step ST4, the module 24 is controlled by the control part 40. For example, as illustrated in FIG. 5A, the module 24 is controlled to deposit a material that constitutes the magnetic layer ML1 on the wafer W1 received in a process container 24c and loaded on a stage 24s. When the module 24 is a sputtering apparatus, the module 24 is controlled such that the material constituting the magnetic layer ML1 is discharged from a target 24t toward the wafer W1. By executing this step ST4, a wafer W2 illustrated in FIG. 5B is obtained.

Subsequently, in the method MT, the wafer W2 is transferred from the module 24 to the module 26 by the transfer device 20. In one embodiment, the wafer W2 is transferred from the module 24 to the film forming apparatus 26A of the module 26 by the transfer device 20. Such an operation of the transfer device 20 related to the transfer of the wafer W2 is controlled by the control part 40.

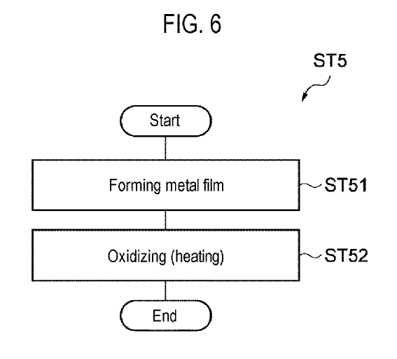

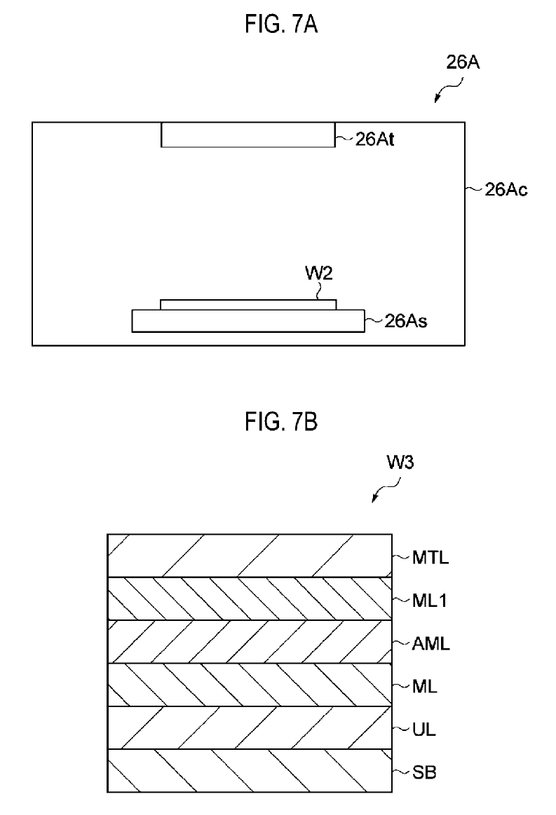

Subsequently, at step ST5, the tunnel barrier layer TL is formed on the magnetic layer ML1. To do this, at step ST5, the module 26 is controlled by the control part 40. FIG. 6 is a flowchart illustrating one embodiment of step ST5 of the method illustrated in FIG. 1. At step ST5 of one embodiment, step ST51 is first executed. At step ST51, a metal film MTL is formed on the magnetic layer ML1. To do this, at step ST51, as illustrated in FIG. 7A, the film forming apparatus 26A of the module 26 is controlled by the control part 40 so as to deposit a metal that constitutes the tunnel barrier layer TL on the wafer W2 received in a process container 26Ac and loaded on a stage 26As. When the film forming apparatus 26A is a sputtering apparatus, the film forming apparatus 26A is controlled to discharge the metal that constitutes the tunnel barrier layer TL from a target 26At toward the wafer W2. By executing this step ST51, a wafer W3 illustrated in FIG. 7B is obtained. That is to say, the wafer W3 having the metal layer MTL formed on the magnetic layer ML1 is obtained.

In one embodiment, subsequently, the wafer W3 is transferred from the film forming apparatus 26A to the oxidizing apparatus 26B by the transfer device 20. Such an operation of the transfer device 20 related to the transfer of the wafer W3 is controlled by the control part 40. Further, when the module 26 is a single film forming apparatus as mentioned above, such a transfer operation may be omitted.

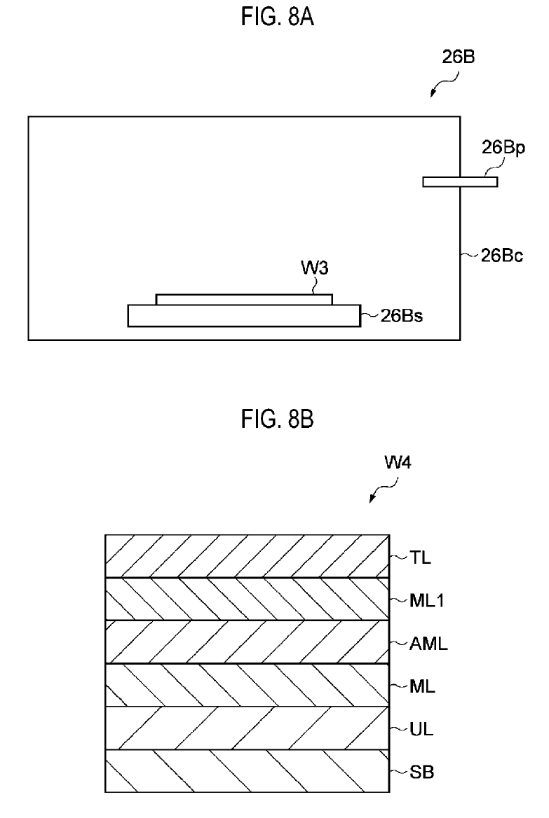

In one embodiment, subsequently, step ST52 is executed to oxidize the metal film MTL. To do this, as illustrated in FIG. 8A, the oxidizing apparatus 26B is controlled by the control part 40 so as to oxidize the metal film MTL of the wafer W3 received in a process container 26Bc and loaded on a stage 26Bs. By such a control operation, the wafer W3 is heated under an oxygen atmosphere. For example, the oxidizing apparatus 26B is controlled to supply heated oxygens from a gas supply part 26Bp to the wafer W3. Thus, as illustrated in FIG. 8B, a wafer W4 having the tunnel barrier layer TL formed therein is obtained. Further, the wafer W4 having the tunnel barrier layer TL formed therein may be obtained by repeating step ST51 and step ST52, as necessary. In addition, at step ST52, oxygen may be supplied to the wafer W3, while heating the wafer W3 by the stage 26Bs. In some embodiments, the heating of the wafer W3 by the stage 26Bs and the supply of heated oxygens to the wafer W3 may be performed in parallel.

Subsequently, in the method MT, the wafer W4 is transferred from the module 26, namely the oxidizing apparatus 26B in one embodiment, to the module 28, by the transfer device 20. Such an operation of the transfer device 20 related to the transfer of the wafer W4 is controlled by the control part 40.

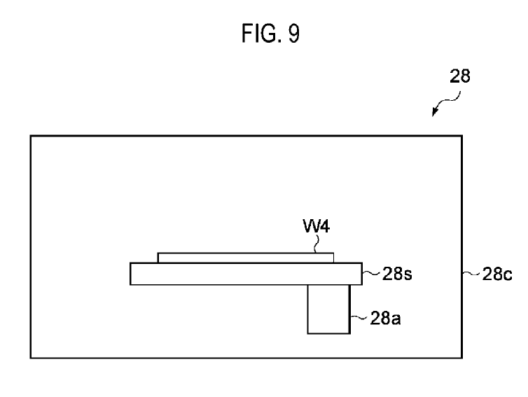

Subsequently, at step ST6, the wafer W4 is cooled. To do this, at step ST6, the module 28 is controlled by the control part 40. Specifically, as illustrated in FIG. 9, the module 28 is controlled to cool the wafer W4 received in a process container 28c and loaded on a stage 28s. For example, at step ST6, in order to cool the wafer W4, a refrigerator 28a coupled to the stage 28s is controlled. At this step ST6, the wafer W4 is cooled down to a temperature equal to or lower than 200 Kelvin, more specifically, 150 Kelvin.

Subsequently, in the method MT, the wafer W4 at the immediately previous stage is transferred from the module 28 to the module 30 by the transfer device 20. Such an operation of the transfer device 20 related to the transfer of the wafer W4 is controlled by the control part 40.

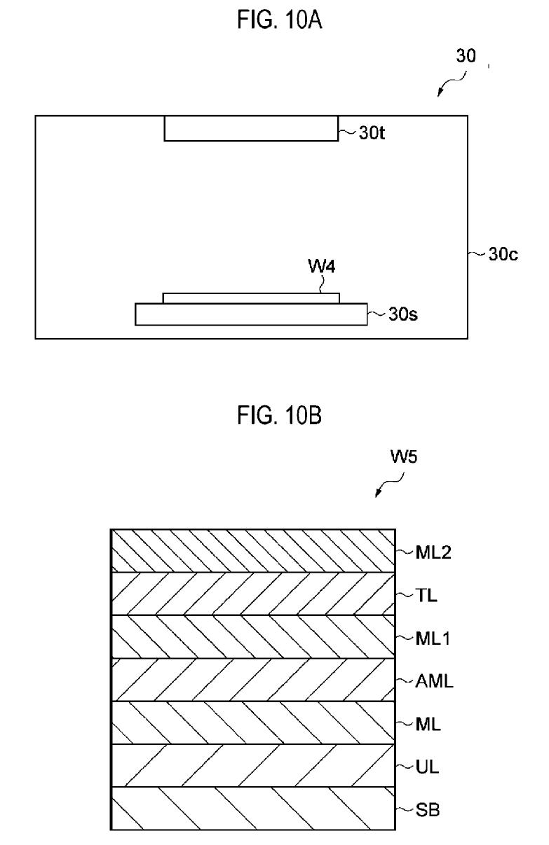

Subsequently, at step ST7, the magnetic layer ML2 is formed on the tunnel barrier layer TL. To do this, at step ST7, the module 30 is controlled by the control part 40. For example, as illustrated in FIG. 10A, the module 30 is controlled to deposit a material that constitutes the magnetic layer ML2 on the wafer W4 received in a process container 30c and loaded on a stage 30s. When the module 30 is a sputtering apparatus, the module 30 is controlled to discharge the material that constitutes the magnetic layer ML2 from a target 30t toward the wafer W4. By executing this step ST7, a wafer W5 illustrated in FIG. 10B is obtained.

Subsequently, in the method MT, the wafer W5 is transferred from the module 30 to the module 32 by the transfer device 20. Such an operation of the transfer device 20 related to the transfer of the wafer W5 is controlled by the control part 40.

Subsequently, at step ST8, the cap layer CL is formed on the magnetic layer ML2. To do this, at step ST8, the module 32 is controlled by the control part 40. For example, the module 32 is controlled to deposit a material that constitutes the cap layer CL. As a result of this step ST8, the MTJ element MD illustrated in FIG. 2 is obtained.

Further, the wafer obtained by executing step ST8 is returned back to any one of the receiving containers 14a to 14d. In one embodiment, thereafter, the wafer may be subjected to a heat treatment. This heat treatment is to crystallize each layer of the MTJ element MD and may be performed in a dedicated heating device provided together with the manufacturing apparatus 10.

According to the aforementioned method MT, the wafer W4 is cooled at step ST6 after the formation (step ST5) of the tunnel barrier layer TL and immediately before the formation (step ST7) of the magnetic layer ML2. Thus, the perpendicular magnetization anisotropic energy of the magnetic layer ML2 is enhanced. This is attributed to the following facts. The wafer is cooled immediately before the formation of the magnetic layer ML2. Thus, the underlying tunnel barrier layer TL is maintained at a low temperature at the time of forming the magnetic layer ML2. This lowers atom mobility available when atoms constituting the magnetic layer ML2 adhere to the tunnel barrier layer TL, thus reducing the peening effect. As a result, the film stress of the magnetic layer ML2 shifts to the tensile stress side, thus lowering an anisotropic energy in an in-plane direction.

In addition, according to the method MT, it becomes possible to enhance an MR ratio (magnetic resistance ratio) of the MTJ element MD. In particular, as the wafer W4 is cooled to a temperature equal to or lower than 200 Kelvin, more specifically, below 150 Kelvin at step ST6, a high MR ratio is obtained. Further, in the aforementioned method MT, the wafer is heated under an oxygen atmosphere at step ST5 of forming the tunnel barrier layer TL. Thus, the cooling effect of step ST6 becomes more effective by cooling the wafer W4 after step ST5 and immediately before step ST7, rather than before step ST5.

Further, in the case where the cooling of the wafer W4 at step ST6 and the formation of the magnetic layer ML2 at step ST7 are performed inside the same module, steps ST6 and ST7 may be continuously performed inside the same module. In this case, the formation of the magnetic layer ML2 may be performed while continuously performing the cooling of the wafer W4.

Hereinafter, various experimental examples will be described, but the present disclosure is not limited thereto.

### Experimental Example 1

In Experimental example 1, the MTJ element illustrated in FIG. 2 was manufactured by the method MT. In Experimental example 1, the cooling temperature of the wafer W4 was set to 100 Kelvin at step ST6. Further, in Experimental example 1, plural types of MTJ elements heated at a plurality of different temperatures after the execution of step ST8 were manufactured. In addition, in Comparative experimental example 1, an MTJ element was manufactured in the same manner as that of Experimental example 1, except that the cooling of step ST6 was not executed. Hereinafter, configurations of the MTJ elements manufactured according to Experimental example 1 and Comparative experimental example 1 are illustrated.

### <Configuration of MTJ Element>

Underlayer UL: Pt layer having a thickness of 3 nm

Magnetic layer ML: Layer obtained by alternately repeatedly forming Co films each having a thickness of 0.45 nm and Pt films each having a thickness of 0.3 nm

Non-magnetic layer AML: Ru layer having a thickness of 0.8 nm

Magnetic layer ML1: CoFeB layer having a thickness of 1.0 nm

Tunnel barrier layer: Magnesium oxide layer set such that the resistance value RA of element is about 10 Ωμm²

Magnetic layer ML2: Layer obtained by laminating CoFeB layer having a thickness of 1.6 nm, tungsten layer having a thickness of 0.3 nm, and CoFeB layer having a thickness of 0.6 nm

Cap layer: Ta layer having a thickness of 5 nm and Ru layer having a thickness of 10 nm

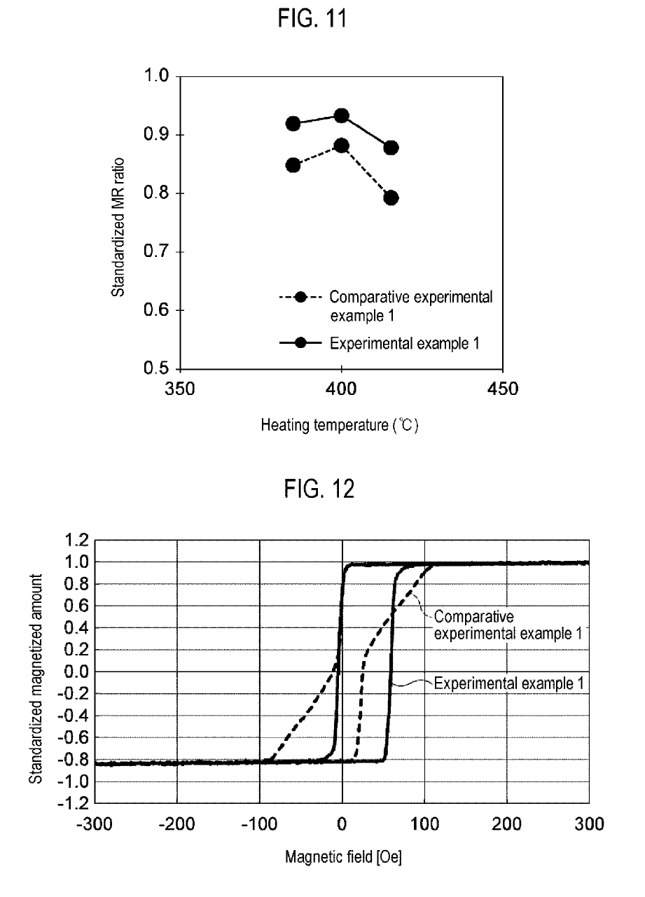

FIG. 11 illustrates a graph of a standardized MR ratio obtained for the MTJ elements of Experimental example 1 and Comparative experimental example 1. In FIG. 11, the horizontal axis represents a heating temperature of the MTJ elements and the vertical axis represents a standardized MR ratio. Further, the standardized MR ratio is obtained by standardizing an MR ratio, which is a variation of tunnel resistance when a magnetization direction is antiparallel and parallel. As illustrated in FIG. 11, the MR ratio of the MTJ element manufactured in Experimental example 1 is greater than the MR ratio of the MTJ element manufactured in Comparative experimental example 1. Thus, it was confirmed that, according to the method MT, i.e., the method of cooling the wafer W4 immediately before the formation of the magnetic layer ML2, it is possible to enhance the MR ratio of the MTJ element.

Further, a magnetization curve of the MTJ element heated at 400 degrees C. for one hour, among the MTJ elements manufactured in Experimental example 1 and a magnetization curve of the MTJ element heated at 400 degrees C. for one hour, among the MTJ elements manufactured in Comparative experimental example 1, were obtained. The result is illustrated in FIG. 12. As illustrated in FIG. 12, the magnetization curve of a hysteresis loop of the MTJ element manufactured in Comparative experimental example 1 is greatly sloped, while the magnetization curve of a hysteresis loop of the MTJ element manufactured in Experimental example 1 is less sloped, which is substantially perpendicular. Here, as the slope of the magnetization curve of a hysteresis loop is small and closer to perpendicular, the perpendicular magnetic anisotropic energy is higher. Thus, as is apparent from FIG. 12, it was confirmed that it is possible to enhance the perpendicular magnetic anisotropic energy of the MTJ element by the method MT.

### Experimental Example 2

In Experimental example 2, an element was manufactured to have the tunnel barrier layer TL formed directly above the underlayer UL by executing step ST1 and steps ST5 to ST8 of the method MT. In Experimental example 2, a cooling temperature at step ST6 was set to 100 Kelvin. Further, in Experimental example 2, plural types of elements including magnetic layers ML2 formed to have different thicknesses were manufactured. In addition, in Comparative experimental example 2, an element was manufactured in the same manner as that of Experimental example 2, except that the cooling of step ST6 was not executed. Hereinafter, configurations of the elements manufactured according to Experimental example 2 and Comparative experimental example 2 are illustrated.

### <Configuration of Element>

Underlayer UL: Ta layer having a thickness of 3 nm

Tunnel barrier layer: Tunnel barrier layer similar to the tunnel barrier layer of Experimental example 1

Magnetic layer ML2: CoFeB layer

Cap layer: Ta layer having a thickness of 50 nm

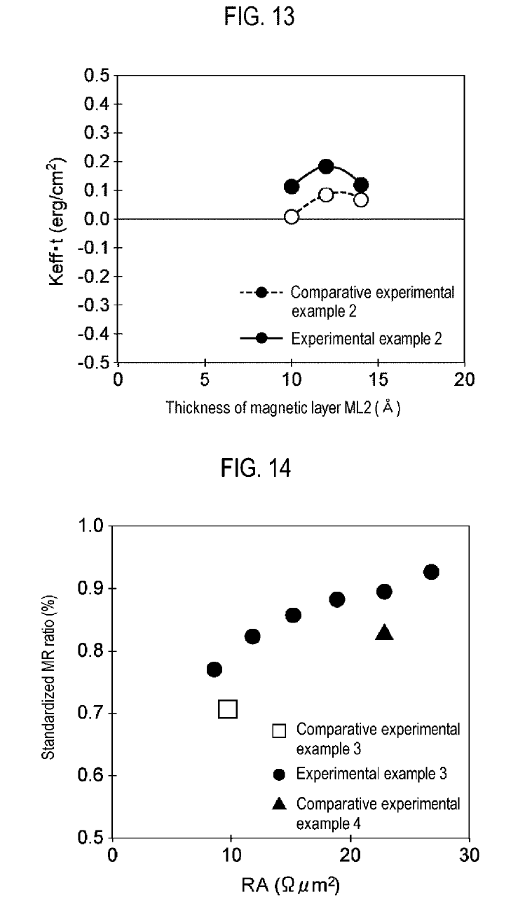

FIG. 13 illustrates a graph of the perpendicular magnetic anisotropic energy of the magnetic layer ML2 of the elements manufactured in Experimental example 2 and Comparative experimental example 2. In FIG. 13, the horizontal axis represents a thickness of the magnetic layer ML2 and the vertical axis represents a perpendicular magnetic anisotropic energy (Keff·t). Here, Keff denotes a density of perpendicular magnetic anisotropic energy of the magnetic layer and t denotes a film thickness of the magnetic layer. Further, the perpendicular magnetic anisotropic energy (Keff·t) was obtained by a vibration sample magnetometer (VSM).

As illustrated in FIG. 13, the perpendicular magnetic anisotropic energy of the magnetic layer ML2 of the element manufactured in Experimental example 2 is higher than the perpendicular magnetic anisotropic energy of the magnetic layer ML2 of the element manufactured in Comparative experimental example 2. Thus, it was confirmed that it is possible to enhance the perpendicular magnetic anisotropic energy by the cooling of step ST6.

### Experimental Example 3

In Experimental example 3, an MTJ element having the same configuration as that of Experimental example 1 was manufactured. Further, in Comparative experimental example 3, an MTJ element was manufactured in the same manner as that of Experimental example 3, except that the cooling of step ST6 was not performed. In addition, in Comparative experimental example 4, an MTJ element was manufactured in the same manner as that of Experimental example 3, except that the wafer was cooled down to 100 Kelvin between step ST3 and step ST4, whereas step ST6 was not performed. Furthermore, in Experimental example 3, MTJ elements having a plurality of different element resistances (RA) were manufactured.

FIG. 14 illustrates a graph of a standardized MR ratio of the MTJ elements manufactured in Experimental example 3, Comparative experimental example 3, and Comparative experimental example 4. In FIG. 14, the horizontal axis represents RA (Ωμm²) and the vertical axis represents a standardized MR ratio. As illustrated in FIG. 14, comparing the MTJ elements having the same RA, the MR ratio of the MTJ element manufactured in Experimental example 3 is higher than the MR ratios of the MTJ elements manufactured in Comparative experimental examples 3 and 4. Thus, it was confirmed that it is effective to cool the wafer W4 after the formation of the tunnel barrier layer TL and immediately before the formation of the magnetic layer ML2.

### Experimental Example 4

In Experimental example 4, an MTJ element having the same configuration as that of Experimental example 1 and manufactured in the same manner was manufactured. However, in Experimental example 4, a plurality of cooling temperatures were set as the cooling temperature at step ST6 and a plurality of MTJ elements were manufactured.

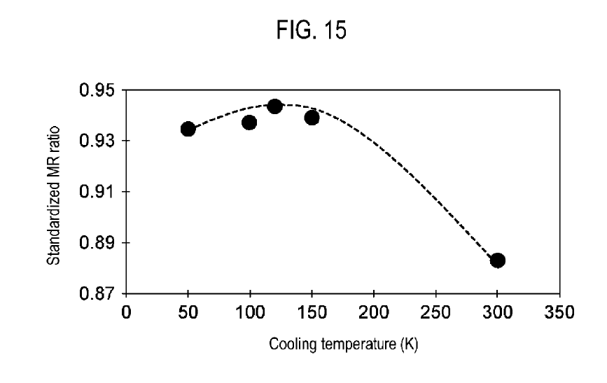

FIG. 15 illustrates a graph of a standardized MR ratio of the plurality of MTJ elements manufactured in Experimental example 4. In FIG. 15, the horizontal axis represents a cooling temperature of step ST6 and the vertical axis represents a standardized MR ratio. From the graph of FIG. 15, it is presumed that the MR ratio of the manufactured MTJ element grows high when the cooling temperature at step ST6 is 200 Kelvin or lower. Further, it was confirmed that the MR ratio of the manufactured MTJ element is further increased when the cooling temperature at step ST6 is 150 Kelvin or lower.

While various embodiments have been described above, the present disclosure is not limited thereto and may be differently modified. For example, as described above, the MTJ element may be a bottom-free type MTJ element. In the bottom-free type MTJ element, an underlayer UL, a magnetic layer ML1 (first magnetic layer), a tunnel barrier layer TL, a magnetic layer ML2 (second magnetic layer), a non-magnetic layer (AML), a magnetic layer ML, and a cap layer CL are sequentially laminated on a substrate SB. Thus, in the case of manufacturing the bottom-free type MTJ element, step ST1, step ST4, step ST5, step ST6, step ST7, step ST3, step ST2, step ST8 are sequentially executed.

As described above, it is possible to enhance a perpendicular magnetic anisotropic energy of a perpendicular magnetization type MTJ element.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for forming a perpendicular magnetization type magnetic tunnel junction element, comprising:
forming a tunnel barrier layer on a first magnetic layer of a workpiece;
cooling the workpiece on which the tunnel barrier layer is formed; and
forming a second magnetic layer on the tunnel barrier layer after the cooling.

2. The method of claim 1, wherein, in the cooling, the workpiece is cooled down to a temperature equal to or lower than 200 Kelvin.

3. The method of claim 1, wherein the tunnel barrier layer is formed of a magnesium oxide, and
wherein the forming a tunnel barrier layer includes:
forming a magnesium layer on the first magnetic layer; and
oxidizing the magnesium layer under an oxygen atmosphere.

4. The method of claim 1, wherein the first magnetic layer and the second magnetic layer contain cobalt, iron and boron.

5. An apparatus for manufacturing a perpendicular magnetization type magnetic tunnel junction element, comprising:
a transfer device configured to transfer a workpiece;
a first module configured to form a first magnetic layer;
a second module configured to form a tunnel barrier layer;
a third module configured to cool the workpiece;
a fourth module configured to form a second magnetic layer; and
a control part configured to control the transfer device, the first module, the second module, the third module, and the fourth module,
wherein the control part is configured to control the transfer device, the first module, the second module, the third module, and the fourth module to:
transfer the workpiece to the first module;
form the first magnetic layer on the workpiece in the first module;
transfer the workpiece from the first module to the second module;
form the tunnel barrier layer on the first magnetic layer in the second module;
transfer the workpiece from the second module to the third module;
cool the workpiece in the third module;
transfer the workpiece from the third module to the fourth module; and
form the second magnetic layer on the tunnel barrier layer in the fourth module.

6. The apparatus of claim 5, wherein the third module is configured to cool down the workpiece to a temperature equal to or lower than 200 Kelvin.

7. The apparatus of claim 5, wherein the second module includes:
a film forming apparatus configured to form a magnesium layer by sputtering magnesium; and
an oxidizing apparatus configured to oxidize the workpiece on which the magnesium layer is formed, under an oxygen atmosphere.
